(19) United States
(12) Patent Application Publication
(10) Pub. No.: US 2012/0262891 A1
(43) Pub. Date: Oct. 18, 2012

(54) POWER CONVERTER

(75) Inventor: Shigekatsu NAGATOMO, Kitakyushu-shi (JP)

(73) Assignee: KABUSHIKI KAISHA YASKAWA DENKI, Kitakyushu-shi (JP)

(21) Appl. No.: 13/426,600

(22) Filed: Mar. 22, 2012

(30) Foreign Application Priority Data
Apr. 13, 2011 (JP) 2011-088831

(51) Int. Cl. H05K 7/00

(52) U.S. Cl. 361/752; 361/679.01

(57) ABSTRACT

A power converter for converting a direct-current power to an alternating-current power or converting an alternating-current power to a direct-current power, includes a box-shaped housing having a front surface, a rear surface, a left surface, a right surface, an upper surface, a lower surface and an opening formed in the front surface. The power converter further includes a reinforcing member including a first reinforcing member and a second reinforcing member which are provided in an internal space of the housing near the opening to intersect each other, the first reinforcing member joined to the left surface and the right surface of the housing, the second reinforcing member joined to the upper surface and the lower surface of the housing.

### CROSS-REFERENCE TO RELATED APPLICATIONS

The present application claims priority under 35 U.S.C. §119 to Japanese Patent Application No. 2011-088831 filed Apr. 13, 2011. The contents of this application are incorporated herein by reference in their entirety.

### BACKGROUND OF THE INVENTION

1. Field of the Invention

The present invention relates to a power converter for converting a direct-current power to an alternating-current power or converting an alternating-current power to a direct-current power.

2. Description of the Related Art

There is known a housing of a power converter for converting a direct-current power to an alternating-current power or converting an alternating-current power to a direct-current power, in which a reinforcing member (a housing reinforcing clasp) having a continuous one-piece structure of loop shape is fixed to the inner surface of the housing (see, e.g., Japanese Utility Model Application Publication H4-59184).

### SUMMARY OF THE INVENTION

In accordance with a aspect of the present invention, there is provided a power converter for converting a direct-current power to an alternating-current power or converting an alternating-current power to a direct-current power, which includes a box-shaped housing having a front surface, a rear surface, a left surface, a right surface, an upper surface, a lower surface and an opening formed in the front surface; and a reinforcing member including a first reinforcing member and a second reinforcing member which are provided in an internal space of the housing near the opening to intersect each other, the first reinforcing member being joined to the left surface and the right surface of the housing, the second reinforcing member being joined to the upper surface and the lower surface of the housing.

### BRIEF DESCRIPTION OF THE DRAWINGS

The objects and features of the present invention will become apparent from the following description of preferred embodiments given in conjunction with the accompanying drawings.

FIG. 1 is a partially-transparent perspective view showing a power converter according to one embodiment of the present invention.

FIG. 2 is an exploded perspective view of the power converter shown in FIG. 1.

FIG. 3 is a front view of the power converter shown in FIG. 1.

FIG. 4 is a partially-transparent perspective view showing a power converter according to a modified example, in which two ducts are provided within a housing.

FIG. 5 is an exploded perspective view of the power converter shown in FIG. 4.

FIG. 6 is a front view of the power converter shown in FIG. 4.

FIG. 7 is a front view showing a power converter according to another modified example, in which a second reinforcing member is formed into a substantially L-like shape.

FIG. 8 is a front view showing a power converter according to a further modified example, in which a second reinforcing member is formed into a substantially T-like shape.

FIG. 9 is a partially-transparent perspective view showing a power converter according to a still further modified example, in which a wind tunnel portion is formed into a rectilinear shape.

### DESCRIPTION OF THE EMBODIMENTS

One embodiment of the present invention will now be described with reference to the accompanying drawings. If an annotation reading “front”, “rear”, “left”, “right”, “up” and “down” exists in the respective drawings, the front, rear, left, right, upper and lower directions in the detailed description of the subject specification will refer to the directions designated by the annotation.

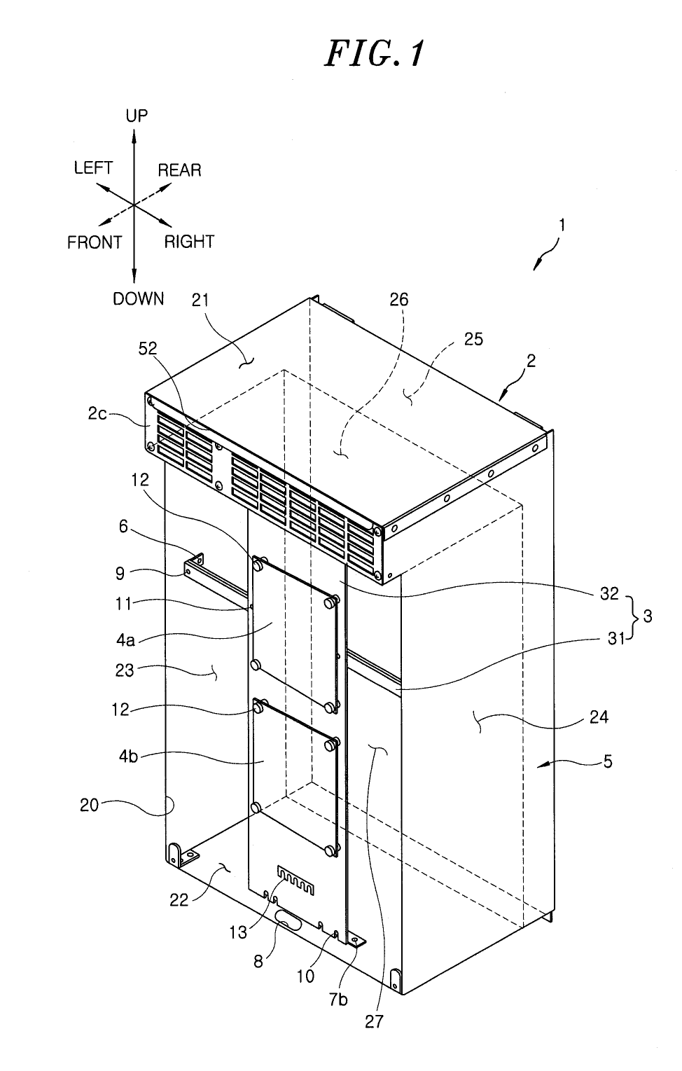

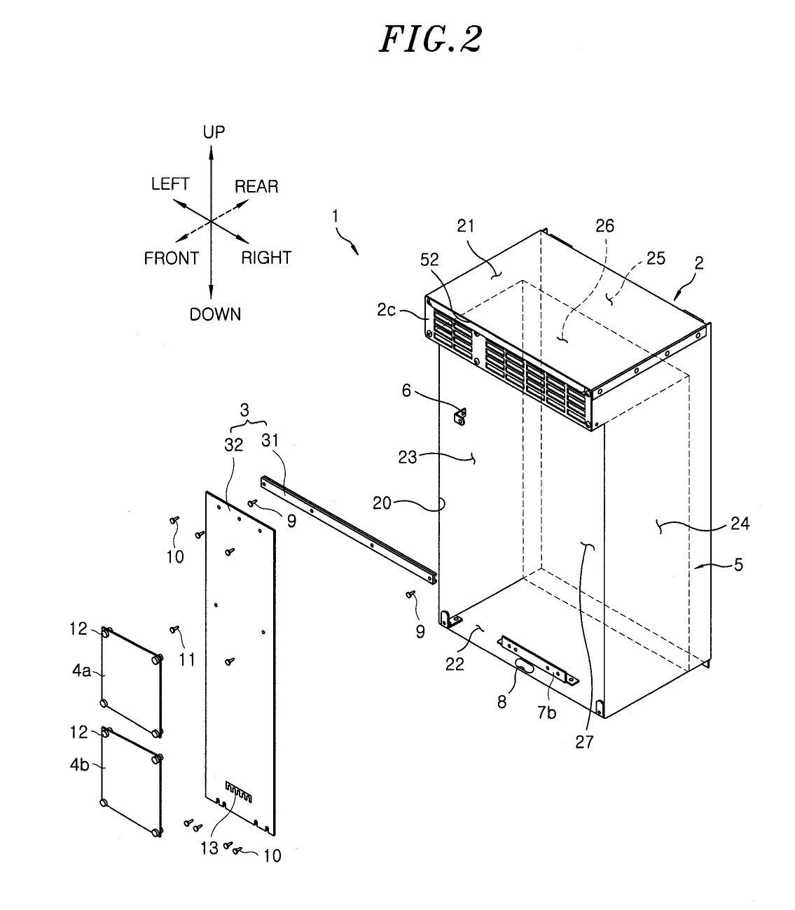

Referring to FIGS. 1, 2 and 3, the power converter 1 of the present embodiment is, e.g., an inverter for converting a direct-current power to an alternating-current power. The power converter 1 includes a housing 2, a reinforcing member 3 and two circuit boards 4a and 4b provided with electronic circuits (not shown) involving the operation of the power converter 1.

The housing 2 has an opening 20 formed on the surface thereof facing forward in the installed state. The housing 2 is formed into a substantially box-like shape by joining metal plates together to form an outer wall. In the illustrated example, the housing 2 is installed in such a posture that the longitudinal direction thereof extends in the up-down direction. A housing cover (not shown) is detachably attached to the opening 20.

When the housing cover is attached in place to cover the opening 20, the inside of the housing 2 as a whole becomes a hollow structure in which various components can be stored. The housing 2 includes an outer upper wall portion 21, an outer lower wall portion 22, an outer left wall portion 23, an outer right wall portion 24 and an outer rear wall portion 25, which are positioned at the upper, lower, left, right and rear sides when seen from the front side. In the present embodiment, a duct 5 as a wind tunnel portion through which a cooling air flows is provided within the housing 2.

The duct 5 is formed of a hollow space having a substantially L-like shape (a vertically-inverted substantially L-like shape in the drawings). The hollow space is surrounded by the outer upper wall portion 21, an inner upper wall portion 26 arranged below the outer upper wall portion 21 in a parallel opposing relationship therewith, the outer left wall portion 23, the outer right wall portion 24, the outer rear wall portion 25 and an inner rear wall portion 27 arranged forward of the outer rear wall portion 25 in a parallel relationship therewith.

The duct 5 is opened at the lower end and the upper front end thereof to communicate with the ambient air. A blower fan (not shown) composed of an axial flow fan or the like is provided in a lower opening 51 of the duct 5. A ventilation cover portion 2c capable of providing sufficient ventilation is arranged in an upper front opening 52 of the duct 5. The ambient air is introduced into the duct 5 from the lower opening 51 as a cooling air inlet port (hereinafter sometimes referred to as “cooling air inlet port 51”). The air thus introduced flows through the duct 5 as a cooling air.

The cooling air is discharged from the upper front opening 52 as a cooling air outlet port (hereinafter sometimes referred to as “cooling air outlet port 52”). In other words, the duct 5 serves as a cooling air flow path. In the illustrated example, the cooling air outlet port 52 slightly protrudes forward beyond the attachment position of the housing cover. Although not shown in the drawings, resistors, reactors, capacitors, semiconductor devices, heat sinks and circuit boards making up the power converter are appropriately arranged within the duct 5.

The duct 5 and the housing 2 are formed into one piece by sharing the adjacent wall portions as set forth above. Alternatively, the duct 5 and the housing 2 may be independently formed by their own wall portions.

An elliptical through-hole 8, through which a plurality of cables such as a power cable or a control cable passes, is formed in the outer lower wall portion 22 near the opening 20.

The reinforcing member 3 is provided within the internal space of the housing 2 near the opening 20. The reinforcing member 3 includes a first reinforcing member 31 and a second reinforcing member 32 which are formed independently of each other.

The first reinforcing member 31 is a narrow flat member whose longitudinal dimension is substantially equal to the left-right directional dimension of the outer lower wall portion 22. The first reinforcing member 31 is arranged in such a posture that the longitudinal direction thereof extends in the left-right direction. The left end portion of the first reinforcing member 31 is fixed by a single screw 9 to a bracket 6 arranged on the inner surface of the outer left wall portion 23. The right end portion of the first reinforcing member 31 is fixed by a single screw (not shown) to a bracket (not shown) arranged on the inner surface of the outer right wall portion 24 in an opposing relationship with the bracket 6 on the inner surface of the outer left wall portion 23.

Thus, the first reinforcing member 31 is joined to the outer left wall portion 23 and the outer right wall portion 24. While the left and right end portions of the first reinforcing member 31 are fixed by a single screw 9 in the present embodiment, the present invention is not limited thereto. Alternatively, the left and right end portions of the first reinforcing member 31 may be fixed by two or more screws or other fasteners.

The second reinforcing member 32 is a flat member having a width greater than the width of the first reinforcing member 31 and is formed into a substantially rectangular shape. The longitudinal dimension of the second reinforcing member 32 is substantially equal to the vertical dimension of the inner rear wall portion 27. The second reinforcing member 32 is arranged in such a posture that the longitudinal direction thereof extends in the up-down direction.

The upper end portion of the second reinforcing member 32 is fixed by three screws 10 to a bracket 7a arranged on the inner surface of the inner upper wall portion 26 (namely, the upper surface exposed to the internal space of the housing 2). The lower end portion of the second reinforcing member 32 is fixed by four screws 10 to a bracket 7b arranged on the inner surface of the outer lower wall portion 22 in an opposing relationship with the bracket 7a on the inner surface of the inner upper wall portion 26. Thus, the second reinforcing member 32 is joined to the inner upper wall portion 26 and the outer lower wall portion 22.

The effect provided by the second reinforcing member 32 joined to the inner upper wall portion 26 and the outer lower wall portion 22 is equivalent to the effect available when the second reinforcing member 32 is joined to the outer upper wall portion 21, which is arranged above the inner upper wall portion 26 in a parallel opposing relationship therewith, and the outer lower wall portion 22. While the upper and lower end portions of the second reinforcing member 32 are each fixed by three or four screws 10 in the present embodiment, the present invention is not limited thereto. Alternatively, each of the upper and lower end portion of the second reinforcing member 32 may be fixed by one screw or five or more screws or other fasteners.

The first reinforcing member 31 and the second reinforcing member 32 are fixedly connected to each other by inserting two screws 11 through the second reinforcing member 32 and fastening the screws 11 to the first reinforcing member 31. As the first reinforcing member 31 and the second reinforcing member 32 are crossed and interconnected in the manner stated above, the reinforcing member 3 has a cruciform shape as a whole.

On the front surface of the second reinforcing member 32, the circuit boards 4a and 4b are arranged side by side along the up-down direction using four bosses 12 for each of the circuit boards 4a and 4b. In other words, the second reinforcing member 32 serves as a board support member for supporting the circuit boards 4a and 4b. The second reinforcing member 32 has a cutout 13 formed in the lower region thereof. The cables are fixed to the cutout 13 through the use of a fastener 13a such as a tying band (cable tie) or the like. The cables 13b drawn from the outside of the housing 2 into the housing 2 through the through-hole 8 of the outer lower wall portion 22 are tied together by the fastener 13a. The fastener 13a is hung on the cutout 13, thereby fixing the cables to the second reinforcing member 32.

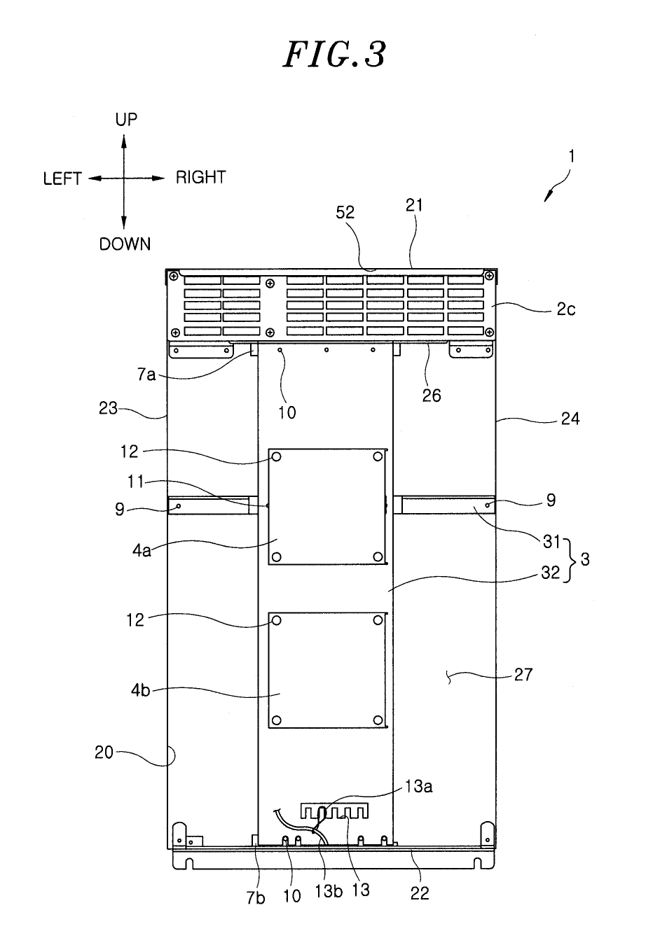

The cutout 13 is formed of, e.g., a rectangular opening having a plurality of lugs protruding from the lower edge thereof. With this configuration, as shown in FIG. 3, the cables 13b drawn into the housing 2 through the through-hole 8 of the outer lower wall portion 22 are tied together by the tying band 13a. Thereafter, the tying band 13a can be hung on one of the lugs of the cutout 13.

As described above, the power converter 1 of the present embodiment includes the housing 2 having the opening 20 formed on the surface thereof facing forward in the installed state and the reinforcing member 3 provided in the internal space of the housing 2 near the opening 20. The housing 2 includes the outer upper wall portion 21, the outer lower wall portion 22, the outer left wall portion 23, the outer right wall portion 24 and the outer rear wall portion 25 positioned at the upper, lower, left, right and rear sides when seen from the front side. The reinforcing member 3 includes the first reinforcing member 31 joined to the outer left wall portion 23 and the outer right wall portion 24 and the second reinforcing member 32 joined to the inner upper wall portion 26 and the outer lower wall portion 22.

By forming the reinforcing member 3 into a substantially cruciform shape using the first reinforcing member 31 and the second reinforcing member 32, it is possible to enhance the anti-vibration strength of the housing 2 in the up-down direction and the left-right direction. Thus, the housing 2 can endure the complex vibration conditions attributable to the diversification of installation conditions of the power converter 1.

Moreover, all that are need is to provide one reinforcing member 3 having a substantially cruciform shape. Accordingly, it is possible to reduce the number of parts and the number of steps of an installation work, as compared with a case where a plurality of reinforcing members extending in the left-right direction is provided on the inner surface of the housing 2 (not specifically shown in the drawings). It is therefore possible to enhance the anti-vibration strength while restraining an increase in the number of parts and in the number of steps of an installation work. As a result, there are provided an effect of reducing the costs involved in purchasing parts and performing works and an effect of saving the manufacturing cost of the power converter 1.

In the present embodiment, the second reinforcing member 32 is a flat member having a width greater than the width of the first reinforcing member 31. This makes it possible to increase the strength against the shearing force acting in the left-right direction of the housing 2 (namely, the force acting to dislocate the outer upper wall portion and the outer lower wall portion 22 in the left-right direction). Since the second reinforcing member 32 has a wide flat shape, it becomes possible to mount the circuit boards 4a and 4b on the surface of the second reinforcing member 32.

In the present embodiment, the second reinforcing member 32 is a flat member having a width greater than the width of the first reinforcing member 31. The circuit boards 4a and 4b are provided on the front surface of the second reinforcing member 32. This enables the second reinforcing member 32 to be used as a board support member. Accordingly, there is no need to additionally provide a board support member, which makes it possible to further reduce the number of parts and the number of steps of an installation work. There is also provided an effect of reducing the vibration transferred to the circuit boards 4a and 4b.

In the present embodiment, the first reinforcing member 31 and the second reinforcing member 32 are formed independently of each other and are fixedly connected to each other. By forming the first reinforcing member 31 and the second reinforcing member 32 independently of each other, it becomes possible to independently design the shapes of the respective members and the materials thereof and to increase the degree of freedom in designing the reinforcing member 3. By fixedly interconnecting the first reinforcing member 31 and the second reinforcing member 32, it is possible to reliably enhance the anti-vibration strength of the housing 2.

In the present embodiment, the second reinforcing member 32 is provided with the cutout 13 formed in the lower region thereof. The cables 13b drawn from the outside of the housing 2 into the housing 2 through the through-hole 8 of the outer lower wall portion 22 are tied together by a fastener 13a. The fastener 13a is hung on the cutout 13, thereby fixing the cables 13b to the second reinforcing member 32. As a result, it is possible to arrange the cables in a well-arranged state.

The present invention is not limited to the embodiment described above but may be modified in many different forms without departing from the scope and spirit of the invention. Certain modified examples will now be described one after another.

### (1) A Modified Example Where Two Ducts are Provided within the Housing

While one duct 5 is provided within the housing 2 in the foregoing embodiment, the present invention is not limited thereto. Alternatively, two ducts may be provided within the housing 2.

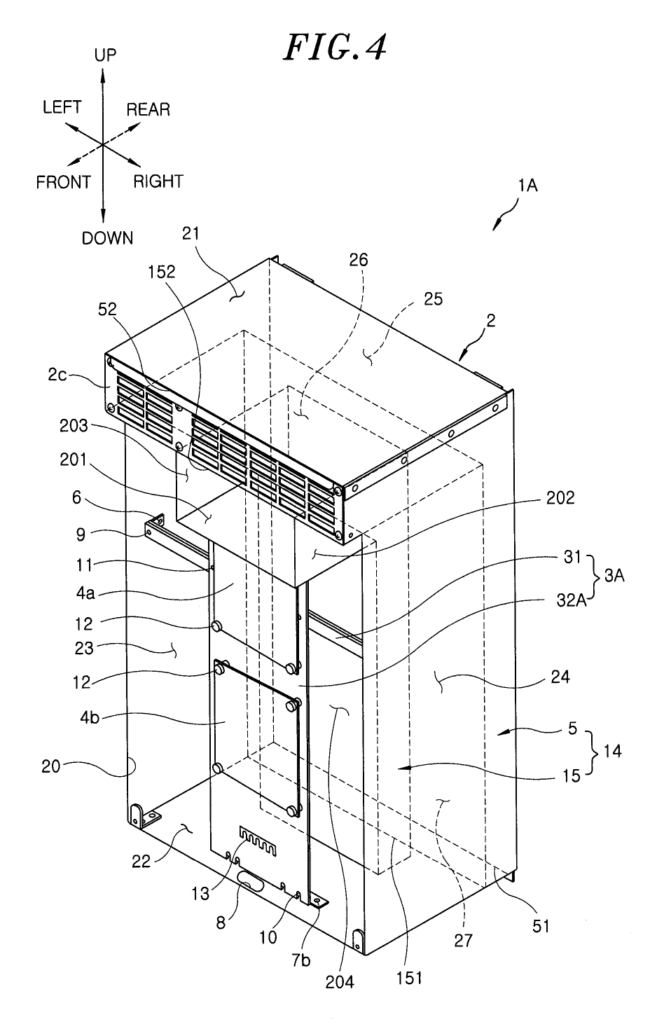

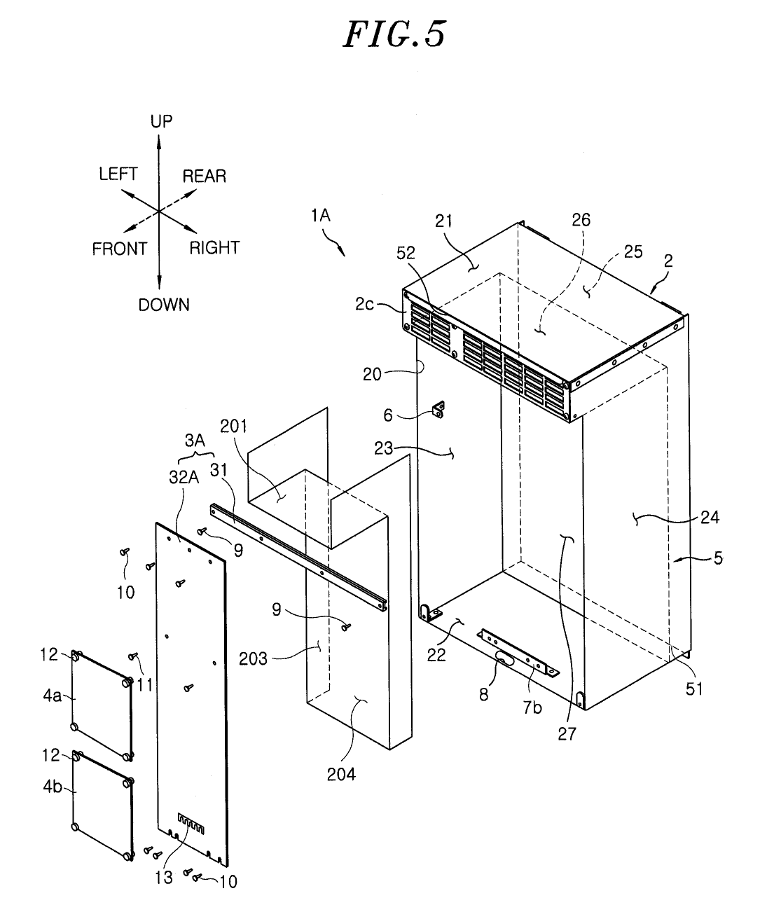

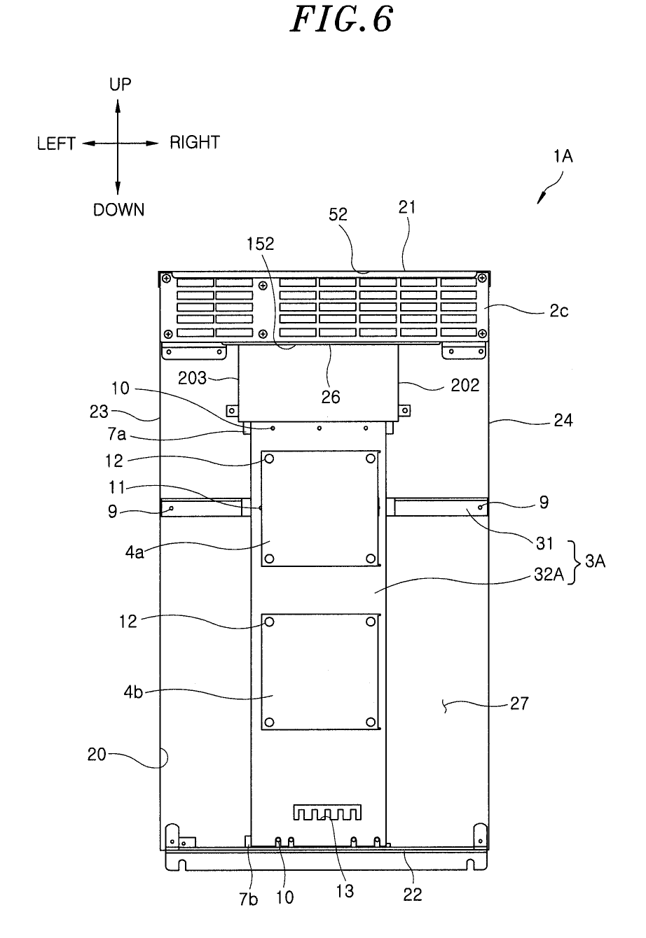

Referring to FIGS. 4, 5 and 6, the power converter 1A according to the present modified example has substantially the same configuration as that of the power converter 1 of the foregoing embodiment, except that an inner duct 15 is additionally provided within the housing 2 and a second reinforcing member 32A is used in place of the second reinforcing member 32.

In the power converter 1A, a wind tunnel portion 14 is provided within the housing 2. The wind tunnel portion 14 includes the afore-mentioned duct 5 (called an “outer duct 5” in the present modified example) and an inner duct 15.

The inner duct 15 is formed of a hollow space having a substantially L-like shape (a vertically-inverted substantially L-like shape in the drawings). The hollow space is surrounded by the inner upper wall portion 26, an inner lower wall portion 201 arranged below the inner upper wall portion 26 in a parallel opposing relationship therewith, an inner left wall portion 203 arranged at the right side of the outer left wall portion 23 in a parallel opposing relationship therewith, an inner right wall portion 202 arranged at the left side of the outer right wall portion 24 in a parallel opposing relationship therewith, the inner rear wall portion 27, and an inner front wall portion 204 arranged frontward of the inner rear wall portion 27 in a parallel opposing relationship therewith.

The inner duct 15 is opened at the lower end and the upper front end thereof to communicate with the ambient air. A ventilation cover portion (not shown) capable of providing sufficient ventilation is arranged in a lower opening 151 of the inner duct 15. A blower fan (not shown) composed of an axial flow fan or the like is provided in an upper front opening 152 of the inner duct 15.

The ambient air is introduced into the inner duct 15 from the lower opening 151 as a cooling air inlet port (hereinafter sometimes referred to as “cooling air inlet port 151”). The air thus introduced flows through the inner duct 15 as a cooling air. The cooling air is discharged from the upper front opening 152 as a cooling air outlet port (hereinafter sometimes referred to as “cooling air outlet port 152”). In other words, the inner duct 15 serves as a cooling air flow path. In the illustrated example, the cooling air outlet port 152 slightly protrudes forward beyond the installation position of the housing cover.

With this configuration, the cooling air flow paths of the outer duct 5 and the inner duct 15 extend substantially parallel to each other and overlap with each other. The cooling air inlet ports 51 and 151 of the outer duct 5 and the inner duct 15 are arranged adjacent to each other. Likewise, the cooling air outlet ports 52 and 152 of the outer duct 5 and the inner duct 15 are arranged adjacent to each other.

The outer duct 5, the inner duct 15 and the housing 2 are formed into one piece by sharing the adjacent wall portions as set forth above. Alternatively, the outer duct 5, the inner duct 15 and the housing 2 may be independently formed by their own wall portions.

The second reinforcing member 32A of the reinforcing member 3A is a flat member having a width greater than the width of the first reinforcing member 31 and is formed into a substantially rectangular shape. The longitudinal dimension of the second reinforcing member 32A is substantially equal to the vertical dimension of the inner front wall portion 204. The second reinforcing member 32A is arranged in such a posture that the longitudinal direction thereof extends in the up-down direction.

The upper end portion of the second reinforcing member 32A is fixed by three screws 10 to a bracket 7a arranged on the inner surface of the inner lower wall portion 201 (namely, the upper surface exposed to the internal space of the housing 2). The lower end portion of the second reinforcing member 32A is fixed by four screws 10 to a bracket 7b arranged on the inner surface of the outer lower wall portion 22 in an opposing relationship with the bracket 7a on the inner surface of the inner lower wall portion 201.

Thus, the second reinforcing member 32A is joined to the inner lower wall portion 201 and the outer lower wall portion 22. The effect provided by the second reinforcing member 32A joined to the inner lower wall portion 201 and the outer lower wall portion 22 is equivalent to the effect available when the second reinforcing member 32A is joined to the outer upper wall portion 21, which is arranged above the inner lower wall portion 201 in a parallel opposing relationship therewith, and the outer lower wall portion 22.

Other configurations of the power converter 1A remain the same as the corresponding configurations of the power converter 1 of the foregoing embodiment.

In the present modified example, it is possible to obtain the same effects as provided by the foregoing embodiment.

### (2) A Modified Example where the Second Reinforcing Member is Formed into a Substantially L-Like Shape

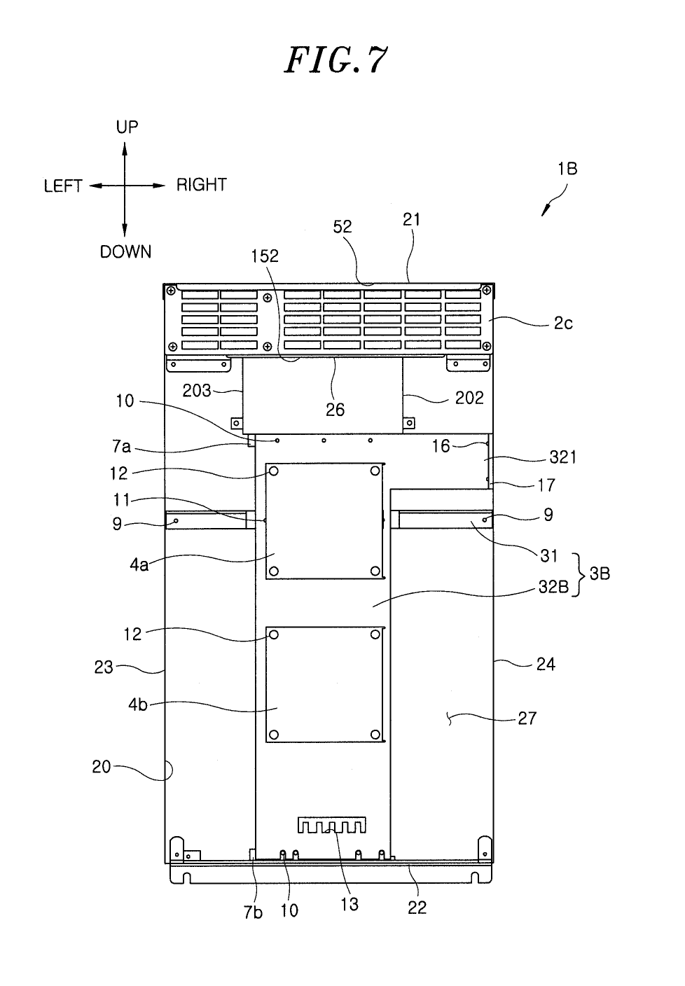

Referring to FIG. 7, the power converter 1B according to the present modified example has substantially the same configuration as that of the power converter 1A of the modified example (1), except that a second reinforcing member 32B is provided in place of the second reinforcing member 32A.

In the power converter 1B, the second reinforcing member 32B of the reinforcing member 3B is a flat member having a width greater than the width of the first reinforcing member 31. The longitudinal dimension of the second reinforcing member 32B is substantially equal to the vertical dimension of the inner front wall portion 204. In the present modified example, the second reinforcing member 32B is formed into a substantially L-like shape and includes an extension portion 321 extending from the upper end portion thereof (or the lower end portion thereof) toward the right side (or the left side) in the installed state.

The second reinforcing member 32B is arranged in such a posture that the longitudinal direction thereof extends in the up-down direction. The upper end portion of the second reinforcing member 32B is fixed by three screws 10 to a bracket 7a arranged on the inner surface of the inner lower wall portion 201. The lower end portion of the second reinforcing member 32B is fixed by four screws 10 to a bracket 7b arranged on the inner surface of the outer lower wall portion 22 in an opposing relationship with the bracket 7a on the inner surface of the inner lower wall portion 201.

Moreover, the end portion of the extension portion 321 of the second reinforcing member 32B extending to the right is fixed by two screws 16 to a bracket 17 arranged in a position differing from the position of the bracket for fixing the right end portion of the first reinforcing member 31 on the inner surface of the outer right wall portion 24 (a position higher than the position of the bracket for fixing the right end portion of the first reinforcing member 31, in the present modified example). Thus, the second reinforcing member 32B is joined not only to the inner lower wall portion 201 and the outer lower wall portion 22 but also to the outer right wall portion 24 in a position differing from the position of the first reinforcing member (a position higher than the position of the first reinforcing member 31, in the present modified example).

Other configurations of the power converter 1B remain the same as the corresponding configurations of the power converter 1A of the modified example (1).

In the present modified example described above, the second reinforcing member 32B of the reinforcing member 3B is formed into a substantially L-like shape and is joined not only to the inner lower wall portion 201 and the outer lower wall portion 22 but also to the outer right wall portion 24 in a position higher than the position of the first reinforcing member 31. With the second reinforcing member 32B of this configuration, it is possible to further enhance the anti-vibration strength of the housing 2.

Alternatively, the second reinforcing member 32B may be joined not only to the inner lower wall portion 201 and the outer lower wall portion 22 but also to the outer left wall portion 23 in a position differing from the position of the first reinforcing member 31. In this case, it is equally possible to obtain the same effects as set forth above.

### (3) A Modified Example Where the Second Reinforcing Member is Formed into a Substantially T-Like Shape

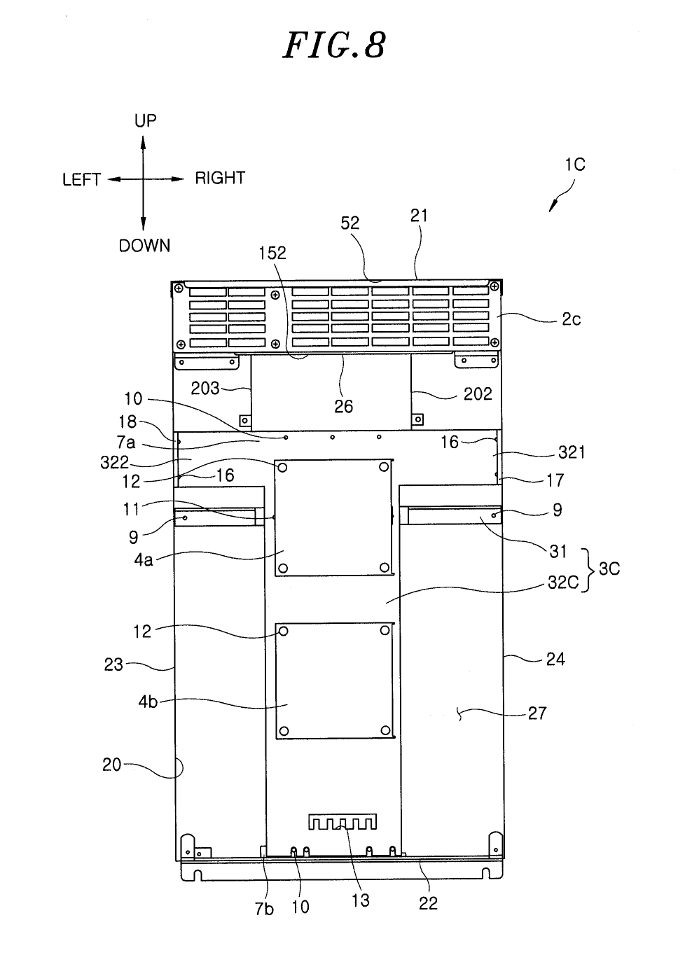

Referring to FIG. 8, the power converter 1C according to the present modified example has substantially the same configuration as that of the power converter 1A of the modified example (1), except that a second reinforcing member 32C is provided in place of the second reinforcing member 32A.

In the power converter 1C, the second reinforcing member 32C of the reinforcing member 3C is a flat member having a width greater than the width of the first reinforcing member 31. The longitudinal dimension of the second reinforcing member 32C is substantially equal to the vertical dimension of the inner front wall portion 204. In the present modified example, the second reinforcing member 32B is formed into a substantially T-like shape and includes an extension portion 321 extending from the upper end portion thereof (or the lower end portion thereof) toward the right side in the installed state and an extension portion 322 extending from the upper end portion thereof (or the lower end portion thereof) toward the left side in the installed state.

The second reinforcing member 32C is arranged in such a posture that the longitudinal direction thereof extends in the up-down direction. The upper end portion of the second reinforcing member 32C is fixed by three screws 10 to a bracket 7a arranged on the inner surface of the inner lower wall portion 201. The lower end portion of the second reinforcing member 32C is fixed by four screws 10 to a bracket 7b arranged on the inner surface of the outer lower wall portion 22 in an opposing relationship with the bracket 7a on the inner surface of the inner lower wall portion 201.

Moreover, the end portion of the extension portion 321 of the second reinforcing member 32C extending to the right is fixed by two screws 16 to a bracket 17 arranged in a position differing from the position of the bracket for fixing the right end portion of the first reinforcing member 31 on the inner surface of the outer right wall portion 24 (a position higher than the position of the bracket for fixing the right end portion of the first reinforcing member 31, in the present modified example). The end portion of the extension portion 322 of the second reinforcing member 32C extending to the left is fixed by two screws 16 to a bracket 18 arranged in a position differing from the position of the bracket 6 on the inner surface of the outer left wall portion 23 (a position higher than the position of the bracket 6, in the present modified example).

Thus, the second reinforcing member 32C is joined not only to the inner lower wall portion 201 and the outer lower wall portion 22 but also to the outer left wall portion 23 and the outer right wall portion 24 in a position differing from the position of the first reinforcing member 31 (a position higher than the position of the first reinforcing member 31, in the present modified example).

Other configurations of the power converter 1C remain the same as the corresponding configurations of the power converter 1A of the modified example (1).

In the present modified example described above, the second reinforcing member 32C of the reinforcing member 3C is formed into a substantially T-like shape and is joined not only to the inner lower wall portion 201 and the outer lower wall portion 22 but also to the outer left wall portion 23 and the outer right wall portion 24 in a position higher than the position of the first reinforcing member 31. With the second reinforcing member 32C of this configuration, it is possible to further enhance the anti-vibration strength of the housing 2 as in the modified example (2).

### (4) A Modified Example Where the Wind Tunnel Portion is Formed into a Rectilinear Shape

While the duct 5 as a wind tunnel portion has a curved structure of substantially L-like shape in the foregoing embodiment, the present invention is not limited thereto. Alternatively, the wind tunnel portion may have a substantially rectilinear shape in the up-down direction.

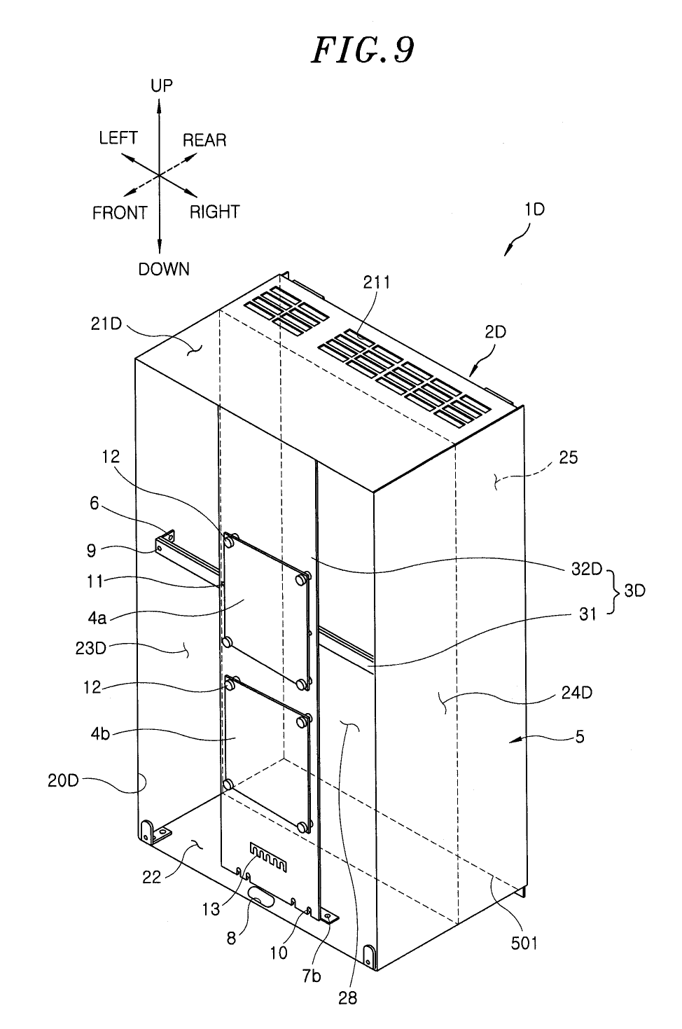

Referring to FIG. 9, the power converter 1D according to the present modified example has substantially the same configuration as that of the power converter 1 of the foregoing embodiment, except that the housing and the wind tunnel portion provided within the housing have different structures than described above and that a second reinforcing member 32D is provided in place of the second reinforcing member 32.

In the power converter 1D, the housing 2D has an opening 20D formed on the surface thereof facing forward in the installed state. The housing 2D includes an outer upper wall portion 21D, an outer lower wall portion 22, an outer left wall portion 23D, an outer right wall portion 24D and an outer rear wall portion 25, which are positioned at the upper, lower, left, right and rear sides when seen from the front side. In the present embodiment, a wind tunnel portion 50 through which a cooling air flows is provided within the housing 2D.

The wind tunnel portion 50 is formed of a rectilinear hollow space surrounded by the outer upper wall portion 21D, the outer left wall portion 23D, the outer right wall portion 24D, the outer rear wall portion 25 and the inner wall portion 28 arranged frontward of the outer rear wall portion 25 in a parallel relationship therewith.

The wind tunnel portion 50 is opened at the lower end thereof to communicate with the ambient air. A plurality of vent holes 211 is formed in the outer upper wall portion 21D positioned at the upper end of the wind tunnel portion 50 so that the wind tunnel portion 50 can communicate with the ambient air. A blower fan (not shown) composed of an axial flow fan or the like is provided in a lower opening 501 of the wind tunnel portion 50.

The ambient air is introduced into the wind tunnel portion 50 from the lower opening 501 as a cooling air inlet port (hereinafter sometimes referred to as “cooling air inlet port 501”). The air thus introduced flows through the wind tunnel portion 50 as a cooling air. The cooling air is discharged from the vent holes 211 as a cooling air outlet port (hereinafter sometimes referred to as “cooling air outlet port 211”). In other words, the wind tunnel portion 50 serves as a cooling air flow path.

The second reinforcing member 32D of the reinforcing member 3D is a flat member having a width greater than the width of the first reinforcing member 31 and is formed into a substantially rectangular shape. The longitudinal dimension of the second reinforcing member 32D is substantially equal to the vertical dimension of the inner wall portion 28. The second reinforcing member 32D is arranged in such a posture that the longitudinal direction thereof extends in the up-down direction.

The upper end portion of the second reinforcing member 32D is fixed by three screws 10 (not shown in FIG. 9) to a bracket 7a (not shown in FIG. 9) arranged on the inner surface of the outer upper wall portion 21D. The lower end portion of the second reinforcing member 32D is fixed by four screws 10 to a bracket 7b arranged on the inner surface of the outer lower wall portion 22 in an opposing relationship with the bracket 7a on the outer upper wall portion 21D. Thus, the second reinforcing member 32D is joined to the outer upper wall portion 21D and the outer lower wall portion 22.

Other configurations of the power converter 1D remain substantially the same as the corresponding configurations of the power converter 1 of the foregoing embodiment.

In the present modified example, it is possible to obtain the same effects as provided by the foregoing embodiment.

### (5) Other Modified Examples

While the first and second reinforcing members of the reinforcing member are formed independently of each other in the foregoing embodiment and modified examples, the present invention is not limited thereto. Alternatively, the first and second reinforcing members may be formed into one piece.

While one first reinforcing member is provided within the housing in the foregoing embodiment and modified examples, the present invention is not limited thereto. Alternatively, two or more first reinforcing members may be provided within the housing.

While an inverter for converting a direct-current power to an alternating-current power has been described as one example of the power converter, the present invention is not limited thereto. The present invention may be applied to a converter for converting an alternating-current power to a direct-current power.

In addition to the above, the foregoing embodiment and modified examples may be used in combination.

While one preferred embodiment of the present invention has been described above, the present invention is not limited to this specific embodiment but may be modified or changed in many different forms without departing from the scope of the invention defined in the claims. Such modifications or changes shall be construed to fall within the scope of the invention.

What is claimed is:

1. A power converter for converting a direct-current power to an alternating-current power or converting an alternating-current power to a direct-current power, comprising:
a box-shaped housing having a front surface, a rear surface, a left surface, a right surface, an upper surface, a lower surface and an opening formed in the front surface; and
a reinforcing member including a first reinforcing member and a second reinforcing member which are provided in an internal space of the housing near the opening to intersect each other, the first reinforcing member being joined to the left surface and the right surface of the housing, the second reinforcing member being joined to the upper surface and the lower surface of the housing.

2. The power converter of claim 1, wherein the second reinforcing member is a flat member greater in width than the first reinforcing member.

3. The power converter of claim 2, further comprising:
at least one circuit board provided on a surface of the second reinforcing member.

4. The power converter of claim 1, wherein the first reinforcing member and the second reinforcing member are formed independently of each other and fixedly connected to each other.

5. The power converter of claim 2, wherein the first reinforcing member and the second reinforcing member are formed independently of each other and fixedly connected to each other.

6. The power converter of claim 3, wherein the first reinforcing member and the second reinforcing member are formed independently of each other and fixedly connected to each other.

7. The power converter of claim 1, wherein the second reinforcing member includes an extension portion joined to at least one of the left surface and the right surface of the housing.

8. The power converter of claim 2, wherein the second reinforcing member includes an extension portion joined to at least one of the left surface and the right surface of the housing.

9. The power converter of claim 3, wherein the second reinforcing member includes an extension portion joined to at least one of the left surface and the right surface of the housing.

10. The power converter of claim 4, wherein the second reinforcing member includes an extension portion joined to at least one of the left surface and the right surface of the housing.

11. The power converter of claim 1, wherein the second reinforcing member has a cutout to which a cable is fixed by use of a fastener.

12. The power converter of claim 2, wherein the second reinforcing member has a cutout to which a cable is fixed by use of a fastener.

13. The power converter of claim 3, wherein the second reinforcing member has a cutout to which a cable is fixed by use of a fastener.

14. The power converter of claim 4, wherein the second reinforcing member has a cutout to which a cable is fixed by use of a fastener.

15. The power converter of claim 5, wherein the second reinforcing member has a cutout to which a cable is fixed by use of a fastener.

16. The power converter of claim 15, wherein the lower surface of the housing has a through-hole formed near the opening to allow passage of the cable therethrough.
